(19) United States
(12) Patent Application Publication
(10) Pub. No.: US 2016/0099135 A1
(43) Pub. Date: Apr. 7, 2016

(54) Rectangular Hollow Sputter Source and Method of use Thereof

(71) Applicant: Kurt J. Lesker Company, Clairton, PA (US)

(72) Inventors: Robert M. Belan, South Park, PA (US); Kurt John Lesker,, III, Bethel Park, PA (US)

(21) Appl. No.: 14/868,688

(22) Filed: Sep. 29, 2015

Related U.S. Application Data
(60) Provisional application No. 62/058,338, filed on Oct. 1, 2014.

(51) Int. Cl. H01J 37/34; C23C 14/34; C23C 14/35

(52) U.S. Cl. CPC H01J 37/3423; C23C 14/35; C23C 14/34; H01J 37/342; H01J 37/3447; H01J 37/3452; H01J 37/3411

(57) ABSTRACT

A rectangular hollow sputtering source includes a box-shaped cathode including therethrough an aperture that is open at a first side and a second side of the box-shaped cathode. A cooling block surrounds the box-shaped cathode and a number of magnets are disposed in the cooling block around the aperture. An electrical insulating part surrounds and electrically isolates the cooling block, the bar magnets, and the cathode from an anode which surrounds the exterior of the electrical insulating part.

### CROSS REFERENCE TO RELATED APPLICATIONS

This application claims the benefit of U.S. Provisional Application No. 62/058,338, filed Oct. 1, 2014, entitled “Rectangular Hollow Sputter Source and Method of Use Thereof”, which is incorporated herein by reference.

### BACKGROUND OF THE INVENTION

1. Field of the Invention

The present invention relates to a physical vapor deposition (PVD) system and, more particularly, to a sputtering source used with said system.

2. Description of Related Art

Cathodes of prior art sputtering sources rely upon electrical biases being applied to the cathode and to a vacuum enclosure of a sputtering system that houses the cathode to establish a suitable magnetic field for the sputtering of material from the cathode. A drawback of this prior art arrangement is need for the cathode to be positioned in proximate relation to the vacuum enclosure.

### SUMMARY OF THE INVENTION

Various preferred and non-limiting examples or aspects of the present invention will now be described and set forth in the following numbered clauses:

Clause 1: A rectangular hollow sputtering source comprises: a box-shaped cathode including therethrough an aperture that is open at a first side and a second side of the box-shaped cathode; a cooling block surrounding the box-shaped cathode; a plurality of magnets in the cooling block around the aperture; an anode; and an electrical insulating part surrounding and electrically isolating the cooling block, the magnets, and the cathode from the anode which surrounds the exterior of the electrical insulating part.

Clause 2: The rectangular hollow sputtering source of clause 1, wherein the cathode can be comprised of a plurality of target segments coupled to the cooling block.

Clause 3: The rectangular hollow sputtering source of clause 1 or 2, can further include a flange that is configured for positioning the rectangular hollow sputter source inside of an enclosure, in spaced relation to the enclosure.

Clause 4: The rectangular hollow sputtering source of any of clauses 1-3, wherein the cooling block can include a cooling line configured to receive a cooling fluid.

Clause 5: A sputtering method comprises: (a) providing the rectangular hollow sputtering source of clause 1 inside of a vacuum enclosure; (b) positioning a first substrate on the first side of the aperture; and (c) generating a plasma that causes atoms to be sputtered from the cathode onto a side of the first substrate that faces the aperture.

Clause 6: The sputtering method of clause 5, can further include, prior to step (c), positioning a second substrate on the second side of the aperture, whereupon the plasma generated step (c) also causes atoms to be sputtered from the cathode onto a side of the second substrate that faces the aperture.

Clause 7: A sputtering system comprises an enclosure and the rectangular hollow sputtering source of clause 1 positioned inside of the enclosure such that atoms sputtered from the cathode of rectangular hollow sputtering source can exit both the first side and the second side of the aperture of the cathode.

Clause 8: A sputtering method comprises (a) providing the rectangular hollow sputtering source of clause 1 inside of a vacuum enclosure; (b) passing a substrate through an aperture of the rectangular hollow sputtering source; and (c) concurrent with step (b), generating a plasma that causes atoms to be sputtered from the cathode onto the substrate as the substrate passes through the aperture.

### BRIEF DESCRIPTION OF THE DRAWING(S)

FIG. 1A is an isolated plan view of an example rectangular, hollow sputtering source;

FIG. 1B is a section taken along line IB-IB in FIG. 1A;

FIG. 2 is a perspective view of the example rectangular, hollow sputtering source of FIG. 1A including an integral flange, cooling lines and power leads; and

FIG. 3 is a schematic illustration of the rectangular, hollow sputtering source of FIG. 2 in a vacuum enclosure of a physical vapor deposition (PVD) system.

### DESCRIPTION OF THE INVENTION

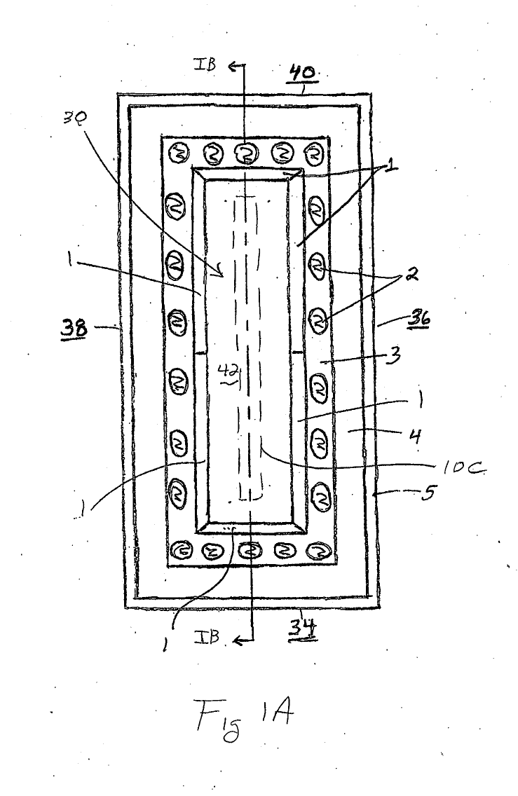

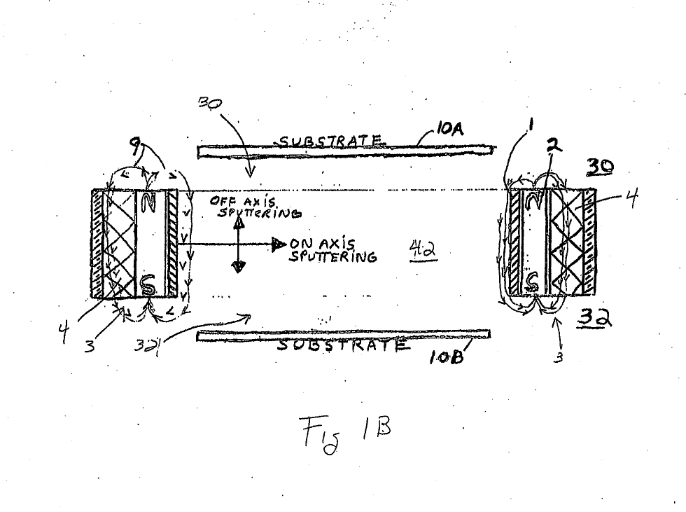

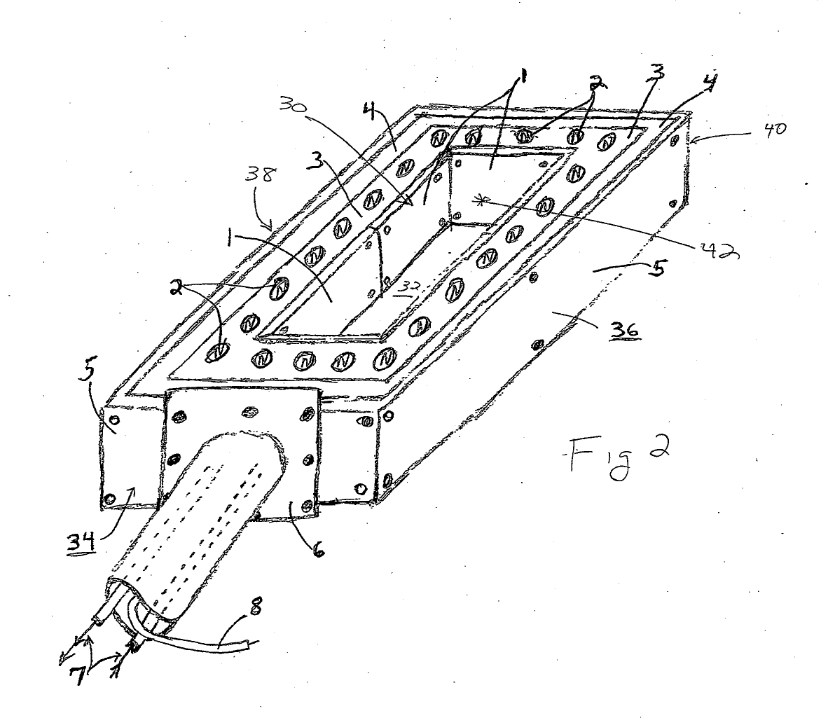

With reference to FIGS. 1A, 1B, and 2, disclosed herein is an example rectangular, hollow sputtering source (RHSS) assembly that includes a cathode made up of rectangular target tiles or segments 1 that form a box that has an aperture 42 therethrough and is open at a top 30 and a bottom 32 of the RHSS assembly. The inner perimeter of the RHSS assembly made of target segments 1 sputters under the proper conditions with most of the energy associated with the sputtering process and the sputtered atoms directed normal to the faces of target segments 1. The primary purpose of RHSS assembly is to sputter deposit a thin film of the target material onto substrates 10A and 10B that are outside of RHSS assembly, i.e., outside of aperture 42, and located normal to the respective top 30 and bottom 32 of RHSS assembly (i.e., off axis to the exposed faces of the target segment 1). With substrates 10A and 10B in these locations, the energy of the sputtered flux is reduced and there is little direct impingement of energetic particles normally associated with on-axis sputtering.

Substrate(s) 10 can be located at top 30, bottom 32, or both top 30 and bottom 32 of the RHSS assembly at a distance from the top 30 and/or bottom 32 of RHSS assembly that can be maximized/minimized for optimal thin film properties. With reduced impingement of energetic particles on the substrate(s) 10, it is possible to sputter materials onto substrate(s) 10 that are comprised of materials sensitive to energetic particles, such as small molecule organic layers e.g. Tris(8-hydroxyquinolinato)aluminum. Substrate(s) 10 can alternatively be comprised of small molecule organic materials often used to fabricate organic electronic devices, such as an Organic Light Emitting Diode (OLED), Organic Field Effect Transistor (OFET), and Organic Photovoltaic (OPV). The cathode formed from target segments 1, described herein, can be used to sputter materials, such as, without limitation, aluminum, silver, magnesium, oxides, such as, for example, SiO2, nitrides, and indium-tin oxide onto an organic electronic device.

The RHSS assembly desirably includes multiple target segments 1 that are fastened to a cooling block 3. Cooling block 3 desirably includes a number of magnets 2, for example, bar magnets, installed in cooling block 3 to produce a uniform (or substantially uniform), flat (homogeneous) magnetic field 9 over the exposed faces of target segments 1 that define aperture 42. A side of cooling block 3 opposite target segments 1 is attached to an electrically insulating part 4 that surrounds and electrically isolates cooling block 3, magnets 2, and target segments 1 from an outer perimeter anode 5 that surrounds the exterior of electrically insulating part 4 and allows RHSS assembly to be mounted to/through a chamber grounding plane via an integral flange 6 (FIG. 2). The sides of anode 5 opposite electrically insulating part 4 form the exterior of RHSS assembly, namely, a front end 34, a left side 38, a right side 36, and a back end 40. Substrate(s) 10A and/or 10B can be positioned in alignment with aperture 42 at top 30 and/or bottom 32 of RHSS assembly to receive a primarily off-axis coating when the target segments 1 are sputtered. On-axis, high energy atoms sputtered from each target segment 1 are generally directed at one or more target segments 1 on the opposite side of aperture 42. A means 8 to supply electrical power to bias the target segments 1 and cooling lines 7 for supplying cooling fluid to cooling block 3 are also provided.

With ongoing reference to FIGS. 1A, 1B, and 2, RHSS assembly includes a plurality of elongated cylindrical or rectangular magnets 2 inserted into cooling block 3 in spaced relation with the north poles of magnets 2 at one of the top 30 or bottom 32 of RHSS assembly and with the south poles of magnets 2 at the other of the top 30 or bottom 32 of RHSS assembly.

Magnets 2 and cooling block 3 are configured such that magnetic field lines 9 produced by magnets 2 extend from each magnet's north pole through the aperture 42 of RHSS assembly over the exposed face of the target segment(s) 1 and return or close on the south pole of the magnet. Target segment(s) 1 may be manufactured in small pieces or tiles that are attached to the flat inner perimeter of cooling block 3 to effectively create a larger surface area than the tile itself. Hence, the target material forming target segment(s) 1 desirably extends completely around the inner perimeter of cooling block 3 defining aperture 42, whereupon target material can be sputtered in any direction, including normal or transverse to the exposed faces of target segment(s) 1 on cooling block 3.

Cooling block 3 may be formed from a solid piece of, for example, copper with apertures for receiving magnets 2 therein. In an example, cooling block 3 includes a pair of cooling lines 7 therethrough, with each cooling line 7 extending through the outer perimeter of cooling block 3. The purpose of cooling lines 7 is to remove heat from RHSS assembly and, more particularly, remove heat from target segments 1 generated by the sputtering process and to keep magnets 2 sufficiently below the Curie temperature for the magnet material forming magnets 2. Cooling lines 7 form a closed-loop cooling circuit within cooling block 3, whereupon cooling fluid (such as water) introduced into one cooling line 7 exits through the other cooling line 7.

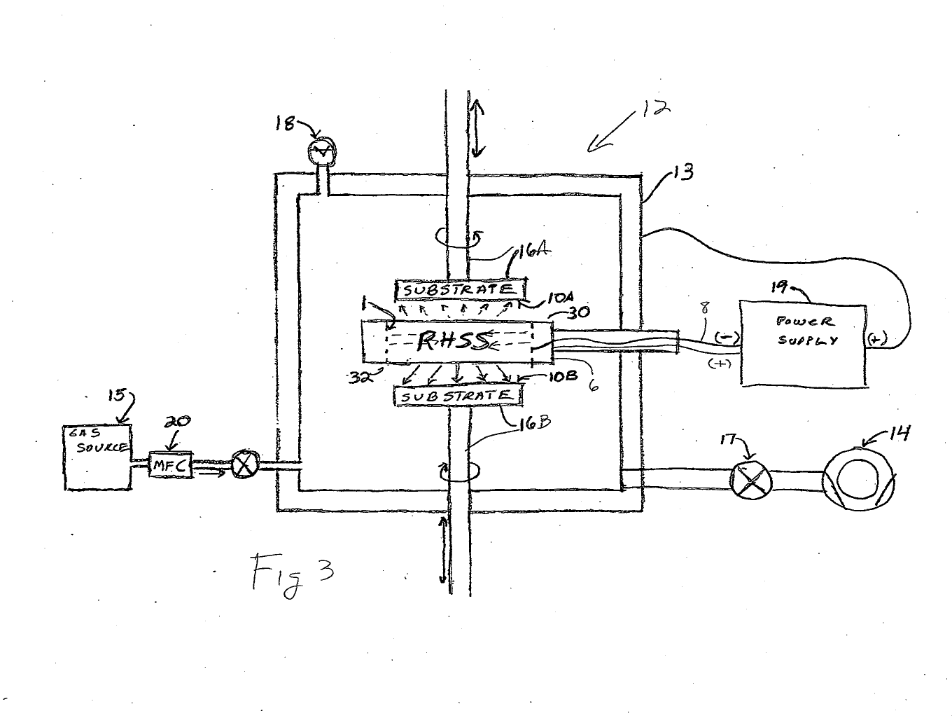

To facilitate electrical connection to RHSS assembly and, more particularly, to sputtering targets 1, cooling block 3 can include power connections (not shown) of any suitable and/or desirable form for connection to power leads 8 that can be coupled to a power supply 19 (FIG. 3) utilized to bias the sputtering target(s) 1 to the potential of a cathode in a sputtering system 12.

With reference to FIG. 3 and with continuing reference to FIGS. 1A, 1B, and 2, RHSS assembly is intended for use in sputtering system 12, such as a physical vapor deposition (PVD) system, and process. A PVD system includes a vacuum enclosure 13 that is sealed from ambient atmosphere to allow air to be removed from the enclosure via a pumping system 14. The evacuated enclosure 13 is then back-filled (from a back-fill gas source 15) with an application-appropriate (inert or reactive) gas at a pressure to allow plasma generation. Back-fill gas flow is controlled by a mass flow controller 20. Adequate pressure of the back-fill gas is typically maintained by controlling a gate or throttling valve 17 with an output signal from a pressure gauge 18. RHSS assembly is mounted inside vacuum enclosure 13 to sputter target material from surface(s) of target segment(s) 1 onto one or more substrates 10 disposed in spaced relation above top 30 and/or bottom 32 of RHSS assembly. Cooling lines 7 are not shown in FIG. 3 for simplicity of illustration.

In use of RHSS assembly, target segment(s) 1 are biased to cathode potential and anode 5 is biased to anode potential via power supply 19. Also, vacuum enclosure 13 is biased to anode potential via power supply 19. In use of RHSS assembly, target segment(s) 1 are biased to a potential more negative than anode 5 and vacuum enclosure 13. In the presence of a suitable pressure and application-appropriate gas in evacuated enclosure 13, the biases are applied to target segment(s) 1 and anode 5 to cause plasma generation in a manner known in the art, which plasma generation sputters atoms from target segment(s) 1 in a manner known in the art. As shown in FIG. 3, substrate 10A and substrate 10B are positioned in spaced relation to top 30 and bottom 32 of RHSS assembly, whereupon off-axis atoms sputtered off of target segment(s) 1 transverse to the face(s) of target segment(s) 1 will coat both substrates 10A and 10B.

Top 10A and/or bottom 10B substrates can be mounted to devices 16A and/or 16B that enable substrates 10A and/or 10B to be rotated about a plane parallel (normal) to top 30 and/or bottom 32 of RHSS assembly and moved closer to or further away from the RHSS assembly. The motion of the substrates 10A and 10B caused by devices 16A and 16B can be linear, rotary, or a combination thereof.

A benefit of the off-axis sputtering of substrates 10A and/or 10B is lower energy deposition when contrasted with an on-axis deposition sputtering for the same thickness deposited film. On-axis means that a substrate 10A or 10B is normal (or substantially normal) to and directly in front of the face of one or more target segment(s) 1 and is directly exposed to sputtered atoms coming off target segment(s) 1 as well as any energetic ions/atoms/electrons generated by the sputtering process. Such on-axis sputtering produces a relatively high temperature on the substrate as the film is deposited and can overheat fragile substrate materials like organic based substrates. Off-axis deposition using the RHSS assembly described herein decreases the substrates' exposure to energetic particles and should lead to a lower substrate temperature during sputtering for a given thickness film deposition.

Of course, it is envisioned that the RHSS assembly can also or alternatively be utilized for on-axis sputtering by passing a substrate 10C (shown in phantom in FIG. 1) to be coated with a film through aperture 42 (in a direction normal to the view in FIG. 1) when target segment(s) 1 are exposed to appropriate sputtering conditions and are releasing sputtered atoms normal to the faces of target segments 1.

The embodiment has been described with reference to a particular example. Modifications and alterations will occur to others upon reading and understanding the foregoing example. Accordingly, the foregoing example is not to be construed as limiting the disclosure.

The invention claimed is:

1. A rectangular hollow sputtering source comprising:
a box-shaped cathode including therethrough an aperture that is open at a first side and a second side of the box-shaped cathode;
a cooling block surrounding the box-shaped cathode;
a plurality of magnets in the cooling block around the aperture;
an anode; and
an electrical insulating part surrounding and electrically isolating the cooling block, the bar magnets, and the cathode from the anode which surrounds the exterior of the electrical insulating part.

2. The rectangular hollow sputtering source of claim 1, wherein the cathode is comprised of a plurality of target segments coupled to the cooling block.

3. The rectangular hollow sputtering source of claim 1, further including a flange configured for positioning the rectangular hollow sputter source inside of an enclosure, in spaced relation to the enclosure.

4. The rectangular hollow sputtering source of claim 1, wherein the cooling block includes a cooling line configured to receive a cooling fluid.

5. A sputtering method comprising:
(a) providing the rectangular hollow sputtering source of claim 1 inside of a vacuum enclosure;
(b) positioning a first substrate on the first side of the aperture; and
(c) generating a plasma that causes atoms to be sputtered from the cathode onto a side of the first substrate that faces the aperture.

6. The sputtering method of claim 5, further including, prior to step (c), positioning a second substrate on the second side of the aperture, whereupon the plasma generated step (c) also causes atoms to be sputtered from the cathode onto a side of the second substrate that faces the aperture.

7. A sputtering system comprising an enclosure and the rectangular hollow sputtering source of claim 1, positioned inside of the enclosure such that atoms sputtered from the cathode of rectangular hollow sputtering source can exit both the first side and the second side of the aperture of the cathode.

8. A sputtering method comprising:
(a) providing the rectangular hollow sputtering source of claim 1 inside of a vacuum enclosure;
(b) passing a substrate through an aperture of the rectangular hollow sputtering source; and
(c) concurrent with step (b), generating a plasma that causes atoms to be sputtered from the cathode onto the substrate as the substrate passes through the aperture.
